(19) United States
(12) Patent Application Publication
(10) Pub. No.: US 2015/0153423 A1
(43) Pub. Date: Jun. 4, 2015

(54) Method and a Device for Determining the Internal Resistance of Battery Cells of a Battery

(71) Applicants: Robert Bosch GmbH, Stuttgart (DE); Samsung SDI Co., Ltd., Yongin-si, Gyeonggi-do (KR)

(72) Inventor: Holger Fink, Stuttgart (DE)

(21) Appl. No.: 14/405,868

(22) PCT Filed: May 24, 2013
(86) PCT No.: PCT/EP2013/060748

§ 371 Date: Dec. 5, 2014

(30) Foreign Application Priority Data
Jun. 8, 2012 (DE) 102012209657.4

(51) Int. Cl. G01R 31/36

(52) U.S. Cl. CPC G01R 31/3662; G01R 31/3627

(57) ABSTRACT

A method for determining the internal resistance of battery cells includes connecting at least one first decoupled battery module to a battery bank to generate a first voltage during the operation of an electric motor. The battery cells are arranged in battery modules of a battery. The battery is connected to the electric motor. The battery modules are arranged at least one battery bank and the battery modules are configured to connect in series to the battery bank to generate an output voltage of the battery and decouple from the battery bank. The method further includes determining the internal resistance of the first battery module during the connection of the battery module. The method further includes decoupling a predetermined number of second battery modules from the battery bank where the second battery modules generate a second voltage similar to the first voltage within a predetermined tolerance limit.

Method and a device for determining the internal resistance of battery cells of a battery

The present invention relates to a method and a corresponding device for determining the internal resistance of the battery cells of the battery modules, arranged in at least one battery bank, of a battery connected to an electric motor, wherein the battery modules are designed, in order to generate an adjustable output voltage of the battery, such that they can each be connected in series to the at least one battery bank of the battery and can be decoupled from the battery bank. The invention also relates to a battery that comprises battery modules which each have at least one battery cell, are arranged in at least one battery bank and, in order to generate an adjustable output voltage of the battery, designed such that they can be connected in series to the battery bank of the battery and can be decoupled from the battery bank. In addition, the invention relates to a motor vehicle having a battery of this type.

### PRIOR ART

Batteries for use in hybrid and electric vehicles are known from the prior art and are referred to as traction batteries, since they are used to feed electric drives.

In an earlier patent application in the name of the applicant, a battery system having a battery with an output voltage adjustable in a stepped manner was described. In the case of the battery of this battery system, the battery cells are not merely connected in series. Rather, the battery system is constructed from battery modules with battery cells connected in series and/or parallel. Such battery modules can be connected or bridged in series via special coupling units to form an individual battery bank. An adjustable output voltage of a battery of such a battery system can be achieved by connecting or bridging a suitable number of batteries to form the battery bank. Battery systems of this type are also referred to here as battery direct converters.

The circuit diagram of such a drive system with a battery direct converter is illustrated in FIG. 1. In accordance with FIG. 1, a drive system 10 comprises a battery system 101 with a battery 100 that is operated with a battery direct converter and is connected to a DC link (not shown), which comprises a capacitor 40. A pulse inverter 50 comprised by the battery system 101 is also connected to the DC link and provides, for the operation of a three-phase electric motor 60 or drive motor, at three outputs in each case via two switchable semiconductor valves (not shown) and two diodes (not shown), sinusoidal voltages phase-shifted in relation to one another. Here, the capacitance of the capacitor 40 must be large enough to stabilize the voltage in the DC link for a period of time in which one of the switchable semiconductor valves is connected. In practice, for example with operation in an electric vehicle, this generally requires a high capacitance in the range typically of several mF.

The battery 100 comprises a battery bank 110 having a plurality of battery modules connected in series, of which only two battery modules 120, 130 are illustrated in the drawing. A charging and separating arrangement 140 can be connected between a battery module 120 and a positive pole 121 of the battery bank 110, which in this case forms the positive battery terminal. A separating arrangement 150 can optionally additionally be connected between a further battery module 130 and a negative pole 131 of the battery bank 110, which in this case forms the negative battery terminal. The separating and charging arrangements 140, 150 are each designed to separate the battery modules 120, 130, which can be coupled at the battery bank 110 by means of a coupling arrangement (not illustrated), from the battery terminals 121, 131 in order to thus connect the battery terminals 121, 131 in a voltage-free manner.

As is also known, 6 to 12 battery cells are combined in a battery module in the case of lithium-ion batteries. This corresponds to a battery module voltage in the range of approximately 18 V, for example in the case when only 6 battery cells are fully charged, whereas 6 battery cells are discharged, and up to 50 V in the case when 12 battery cells are fully charged.

In another patent application in the name of the applicant, a method for determining the internal resistance of the battery cells or battery modules contained in the battery of a battery direct converter is described. The method there is determined in that the output voltage of the battery of the battery direct converter changes during the determination of the internal resistance of the battery cells or battery modules provided in the battery, which in many cases may have a detrimental effect and may lead to problems depending on the operating state of the drive or may not be tolerable. A battery direct converter in which the specified method for determining the internal resistance of the battery cells or battery modules contained in the battery of the battery direct converter is performed therefore cannot be used arbitrarily in conjunction with inverters, electric machines and the associated control and management systems thereof.

In battery systems that are constructed in accordance with the architecture of a battery direct converter, it is possible that the battery modules are individually connected to the battery bank and decoupled from the battery bank. This can be used to selectively perform the determination of the internal resistance of the battery cells contained in a battery module of the battery provided in the battery direct converter.

A disadvantage with the method known from the prior art for determining the internal resistance of the battery cells or battery modules contained in the battery of a battery direct converter is that the output voltage of the battery comprised by the battery direct converter is considerably increased by the connection of the at least one battery module for the battery cells of which the internal resistance is to be determined.

### DISCLOSURE OF THE INVENTION

A method and a device according to the accompanying independent claims are created in accordance with the invention.

A method for determining the internal resistance of the battery cells of the battery modules, arranged in at least one battery bank, of a battery connected to an electric motor is provided. Here, in order to generate an adjustable output voltage of the battery, each of the battery modules is designed such that it can be connected in series to the battery bank of the battery and can be decoupled from the battery bank. In accordance with the invention, during the operation of the electric motor, at least one first battery module decoupled from the battery bank is connected to the battery bank and the internal resistance of the battery cells of the at least one first connected battery module is determined. Furthermore, at the same time as the connection of the first battery module, a suitable number of second battery modules, which on the whole generate a voltage matching the voltage generated by the first battery module within predetermined tolerance limits, are decoupled from the battery bank.

In accordance with the invention, a device for determining the internal resistance of the battery cells of the battery modules, arranged in at least one battery bank, of a battery connectable to an electric motor is also provided. Here, the battery modules for generating an adjustable output voltage of the battery are each designed such that they can be connected in series to the battery bank of the battery or can be decoupled from the battery bank. In accordance with the invention, the device is designed, during the operation of the electric motor, to connect to the battery bank at least one first battery module decoupled from the battery bank and to determine the internal resistance of the battery cells of at least one first connected battery module. Furthermore, the device is designed, at the same time as the connection of the first battery module, to decouple from the battery bank a sufficient number of second battery modules, which on the whole generate a voltage matching the voltage generated by the first battery module within predetermined tolerance limits.

The invention particularly relates to batteries that are operated in conjunction with a battery direct converter (BDC) and are connected to a DC link of an inverter.

In particular, the battery cells of at least one first battery module connected to the battery bank are excited by means of a stepped current, and the stepped response voltage generated by the excited battery cells is recorded and evaluated in order to determine the internal resistance of these excited battery cells.

A key advantage of the present invention is that the specific mode of operation and the specific operation possibilities of battery direct converters are used in order to determine as easily and accurately as possible the internal resistance of the battery cells of the battery modules provided in the battery of a battery direct converter, without having to change the output voltage of the battery.

In other words, in particular a stepped excitation voltage in the form of a current with stepped course is applied to the battery cells of a battery module in order to determine the internal resistance of battery cells of the battery modules of a battery comprised by a battery direct converter, wherein a response of the battery cells of the battery module, which response is present in the form of a voltage having a stepped course, is also recorded and evaluated. So that the output voltage of the battery comprised by the battery direct converter does not change considerably, another battery module with comparable module voltage is disconnected for compensation. The determination of the internal resistance of the battery cells of the battery modules of the battery comprised by a battery direct converter can thus be performed without influencing the operation of an electric motor (electric drive) connected to the battery converter.

In accordance with the invention, the increase of the output voltage of a battery of a battery direct converter is prevented by disconnecting another battery module with comparable module voltage at the same time as, in particular, an individual battery module is connected, for which the internal resistance of the battery cells is to be determined.

So that the output voltage of the battery of the battery direct converter does not change considerably with this process, certain boundary conditions have to be met during the operation of the battery direct converter. Here, various concepts are possible, which will be explained hereinafter on the basis of a number of examples.

Here, all of these concepts in principle have the objective of providing at least one battery module in the battery of the battery direct converter, which battery module has approximately the same state of charge or the same module voltage as the battery module for the battery cells of which the internal resistance is to be determined.

In a particularly advantageous embodiment of the invention, a number of, or all, battery modules of the battery bank are assigned to at least one battery module group, wherein the battery modules of the battery module group are used during operation of the electric motor in such a way that they have the same state of charge and/or the same battery module voltage. Here, at least one first battery module, for the battery cells of which the determination of the internal resistance is to be performed, and at least one second battery module, which is to be decoupled from the battery bank at the same time as the connection of the first battery module to the battery bank, are selected from the battery module group.

The battery module group preferably comprises a constant battery module number or a battery module number that changes dynamically during the operation of the electric motor. If a number of battery module groups are provided, at least two battery module groups can have the same battery module number and/or at least two battery module groups can have a different battery module number.

In other words, in particular at least two battery modules in the battery direct converter are always operated in pairs such that they have the same state of charge or the same module voltage within parameterizable limits. In accordance with the invention, in particular with a drive by means of electric motor used over a relatively long period of time, for example during a journey, at least two battery modules are thus connected to the battery bank via the controller of the battery direct converter or decoupled from the battery bank at the same time or are connected to the battery bank or decoupled from the battery bank alternately at short intervals in order to prevent the states of charge from drifting away from one another.

Furthermore, at least three battery modules and at most all battery modules of the battery direct converter can also be operated as a group (cluster) in the manner described above, wherein the battery modules of the groups thus have approximately the same state of charge. Here, the battery modules of the battery direct converter can be divided into a number of such groups (clusters). The number of battery modules contained in a group may be constant. Alternatively, the number of battery modules involved in the different groups may not be the same and may change dynamically during operation.

Furthermore, the battery modules in the battery direct converter may be operated such that the output voltage of the battery contained in the battery direct converter, when the battery module for the battery cells of which the internal resistance is to be determined is connected, does not increase when at least one further battery module is additionally connected and at least two further battery modules are disconnected.

In a particular embodiment of the invention, at a certain moment in time, the at least one first battery module, decoupled from the battery bank, for the battery cells of which the internal resistance is to be determined is selected to be the first battery module for which a number of second connected battery modules, in particular a single second connected battery module, is provided that has/have a voltage on the whole matching the voltage that can be generated by the selected first battery module within predetermined tolerance limits.

In this particular embodiment, the controller of the battery direct converter determines the current module voltages of the battery modules of which the connection to the battery bank by a simultaneous disconnection of one or more other battery modules from the battery bank can be considered as practically output-neutral. Here, the internal resistance determination may not be performed for all battery modules at any moments in time.

A further aspect of the invention relates to a battery that can be connected to an electric motor and has a plurality of battery modules which each comprise at least one battery cell, are arranged in at least one battery bank and, in order to generate an adjustable output voltage of the battery, are designed such that they can be connected in series to the battery bank of the battery and can be decoupled from the battery bank. The battery further has the above-described device according to the invention for determining the internal resistance of the battery cells of the battery modules of the battery.

In accordance with the invention, the battery is a lithium-ion battery in particular.

The invention also relates to a vehicle having a battery that is connectable to the electric motor of the vehicle and that has a plurality of battery modules which each comprise at least one battery cell, are arranged in at least one battery bank and, in order to generate an adjustable output voltage of the battery, can be connected in series to the battery bank and can be decoupled from the battery bank. The battery is equipped with the device according to the invention in order to determine the internal resistance of the battery cells of the battery modules of the battery.

Advantageous developments of the invention are specified in the dependent claims and are described in the description.

### DRAWINGS

Exemplary embodiments of the invention will be explained in greater detail on the basis of the drawings and the following description. In the drawings:

FIG. 1 shows the circuit diagram of a battery operated in conjunction with a battery direct converter and known from the prior art, which battery is connected to an electric motor,

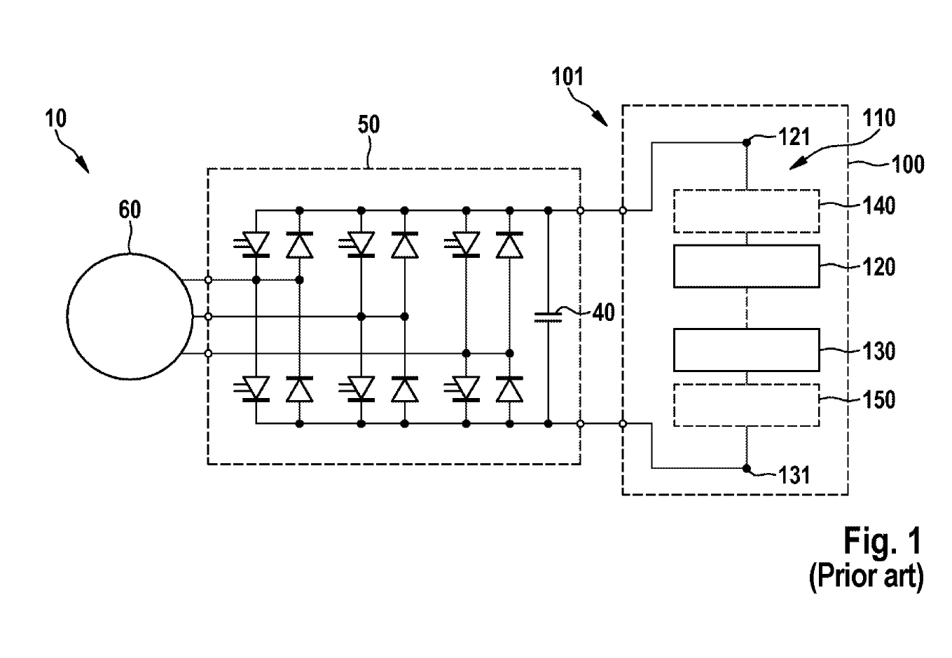

FIG. 2 shows the circuit diagram of a battery which is operated with a battery direct converter and which is connected to an electric motor and to a device for determining the internal resistance of the battery cells of the battery modules contained in the battery in accordance with a first embodiment of the invention, and

FIG. 3 shows the graph indicating an output voltage of the battery from FIG. 2 depending on the number of battery modules connected to the battery bank of the battery, wherein the battery modules are used during the operation of the electric motor by means of the device illustrated in FIG. 2 in accordance with the first embodiment of the invention, in such a way that they each have the same module voltage.

### EMBODIMENTS OF THE INVENTION

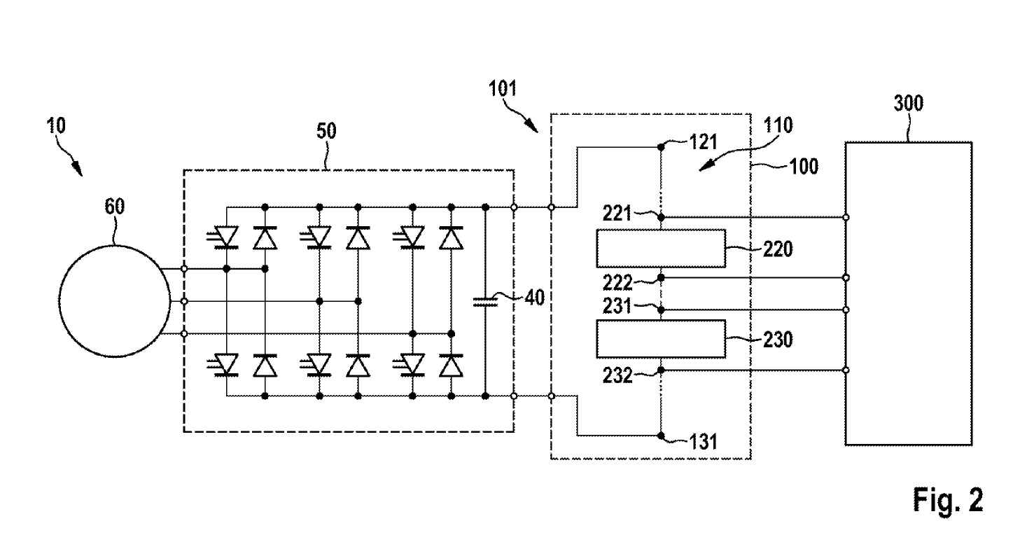

FIG. 2 shows the circuit diagram of a drive system 10, which comprises a battery 100 connected to an electric motor 60 in accordance with a first embodiment of the invention, which battery is operated with a battery direct converter. A battery system 101 comprises the battery 100, which is connected to a DC link (not shown), which comprises a capacitor 40. A pulse inverter 50 comprised by the battery system 101 is also connected to the DC link and, for the operation of a three-phase electric motor (electric drive motor) 60, provides at three outputs, in each case via two switchable semiconductor valves (not shown) and two diodes (not shown), sinusoidal voltages phase-shifted in relation to one another.

The battery 100 comprises a battery bank 110 having a plurality of battery modules connected in series, of which only one first battery module 220 and one second battery module 230 are illustrated explicitly. The battery modules 220, 230 are connected between a positive pole 121 of the battery bank, which forms the positive terminal of the battery 100, and a negative pole 131 of the battery bank 110, which forms the negative terminal of the battery. The battery modules 220, 230 can each be connected to the battery bank 110 and decoupled from the battery bank 110 by means of a coupling device (not illustrated). In order to generate a desired output voltage of the battery 100, a suitable number of battery modules 220, 230 are connected to the battery bank 110.

A device 300 for determining the internal resistance of battery cells (not illustrated) of the battery modules 220, 230 contained in the battery 100 is connected to the battery 100.

All first battery modules 220 of the battery 100 are electrically connected via the connections 221 and 222 to the device 300 according to the invention. All second battery modules 230 of the battery 100 are electrically connected via the connections 231 and 232 to the device 300 according to the invention.

The device 300 is designed to measure the voltages of the individual battery modules 120, 130 and comprises a control device (not illustrated), which inter alia obtains information concerning the voltages of the battery modules 220, 230 and communicates with the battery modules via a communications interface (not illustrated).

By means of the device 300 according to the invention, the first battery module 220 and the second battery module 230 are used in such a way during operation of the electric motor 60 to generate the output voltage of the battery 100 that the first battery module 220 and the second battery module 230 always have the same module voltage. To this end, the first battery module 220 and the second battery module 230 are connected to the battery bank 110 or decoupled from the battery bank 110 at the same time by means of the control device comprised by the device 300. The first battery module 220 and the second battery module 230 can also be connected to the battery bank 110 or disconnected from the battery bank 110 alternately at short intervals by means of the control device comprised by the device 300 in order to prevent the states of charge from drifting away from one another.

When the internal resistance of the battery cells of the first battery has to be determined, the first battery module 220 decoupled from the battery bank 110 is connected by means of the control device comprised by the device 300, and the second battery module 230 connected to the battery bank 110 is decoupled from the battery bank 110. The device 300 then determines the internal resistance of the battery cells of the first connected battery module 220 by exciting the battery cells of the first battery module 220 connected to the battery bank by means of a stepped current and by recording and evaluating the stepped response voltage generated by the excited battery cells. During the determination of the internal resistance of the battery cells of the first battery module 220, the output voltage of the battery 100 remains practically constant.

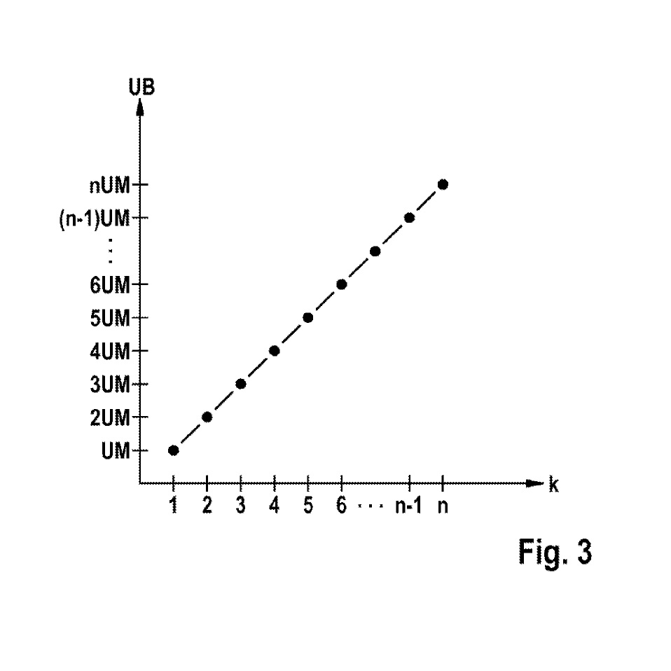

FIG. 3 shows the output voltage UB of the battery 100 from FIG. 2 depending on the number k of battery modules connected to the battery bank 110 of the battery 100, wherein the battery modules are used by means of the device 300 illustrated in FIG. 2 during operation of the electric motor 60 in such a way that they each have the same module voltage UM. The output voltage UB of the battery 100 illustrated depending on the number k of battery modules connected to the battery bank 110 is linear and follows the relation UB=k·UM, wherein 1<k<n. Here, n is the maximum number of battery modules that can be connected to the battery bank 110. The maximum output voltage can then assume the value n·UM accordingly. The black dots represent the individual measurement points.

1. A method for determining an internal resistance of battery cells, comprising:
connecting at least one first battery module to a battery bank to generate a first voltage during the operation of an electric motor, wherein the battery cells are arranged in battery modules of a battery connected to the electric motor and the battery modules are arranged in at least one battery bank and configured to connect in series to the battery bank to generate an output voltage of the battery and decouple from the battery bank and the at least one first battery module is decoupled from the battery bank before the connection;
determining the internal resistance of battery cells of the at least one first battery module during the connection of the at least one first battery module; and
decoupling a predetermined number of second battery modules from the battery bank, wherein the predetermined number of second battery modules generate a second voltage similar to the first voltage within a predetermined tolerance limit.

2. The method as claimed in claim 1, wherein the determination of the internal resistance of battery cells further includes:
exciting the battery cells with a stepped current; and
recording and evaluating a stepped response voltage generated by the excited battery cells.

3. The method as claimed in claim 1, further comprising:
operating a battery module group during operation of the electric motor to enable the battery module group to have at least one of a same state of charge and a same battery module voltage, wherein a portion of the battery modules of a battery bank are assigned to a battery module group and one or more of the at least one first battery module are configured to be connected and a corresponding number of second battery modules are configured to be decoupled are assigned to the battery module group.

4. The method as claimed in claim 3, wherein the battery module group includes a number of battery modules, wherein the number is constant or changes dynamically during the operation of the electric motor.

5. The method as claimed in claim 3, wherein if a number of battery module groups are provided, at least two battery module groups each have at least one of the same battery module number and a different battery module number.

6. The method as claimed in claim 1, further comprising:
selecting the at least one first battery module for connection to the battery bank during the selection of the second battery modules.

7. A device, comprising:
a battery connected to an electric motor, the battery including:
battery banks; and
battery modules arranged in at least one battery bank, the battery modules including battery cells and the battery modules configured to connect to the at least one battery bank in series to generate an output voltage of the battery and to decouple from the at least one battery bank;
wherein the device is configured to:
connect at least one first battery module to the at least one battery bank to generate a first voltage during the operation of the electric motor, wherein the at least one first battery module is decoupled from the at least one battery bank before the connection;
determine the internal resistance of the battery cells of the at least one first battery module during the connection of the at least one first battery module; and
decoupling a predetermined number of second battery modules from the battery bank, wherein the number of second battery modules generate a second voltage similar to the first voltage within a predetermined tolerance limit.

8. The device as claimed in claim 7, wherein the device is further configured to:
excite battery cells of the at least one first battery module with a stepped current; and
record and evaluate a stepped response voltage generated by the excited battery cells to determine the internal resistance of the excited battery cells.

9. The device as claimed in claim 7, wherein the device is further configured to:
select a number of batter modules, the number being either constant changing during the operation of the electric motor;
assign the number of battery modules to at least one battery module group; and
use the battery modules during the operation of the electric motor to enable each of the battery modules to have at least one of a same state of charge and a same battery module voltage, wherein one or more of the at least one first battery module and a corresponding number of second battery modules are battery modules selected from the battery module group.

10. The device as claimed in claim 7, wherein the device is further configured to:
select the at least one first battery module for connection to the battery bank when the first voltage is the same as the second voltage within a predetermined tolerance limit, wherein the at least one first battery module is decoupled from the battery bank prior to the connection.

11. A battery, comprising:
a number of battery modules, each of the battery modules include at least one battery cell,
at least one battery bank, wherein the battery modules are arranged in the at least one battery bank and the battery modules are configured to connect in series to the at least one battery bank to generate an output voltage of the battery and to decouple from the at least one battery bank;
the battery being comprised in a device configured to:
connect at least one first battery module to the at least one battery bank to generate a first voltage during the operation of the electric motor, wherein the at least one first battery module is decoupled from the at least one battery bank prior to the connection;
determine the internal resistance of the battery cells of the at least one first battery module during the connection of the first battery module; and
decoupling a predetermined number of second battery modules from the battery bank, wherein the number of second battery modules generate a second voltage similar to the first voltage within a predetermined tolerance limit.

12. The battery as claimed in claim 11, wherein the battery is arranged in a drive system of the vehicle.
